(19) United States
(12) Patent Application Publication
(10) Pub. No.: US 2013/0114192 A1
(43) Pub. Date: May 9, 2013

(54) ELECTRONIC DEVICE HAVING DETECTOR WINDOW

(71) Applicants: HE-LI WANG, Shenzhen City (CN); WEI LIU, Shenzhen City (CN); YONG-JUN YU, Shenzhen City (CN); XIAO-HUI ZHOU, Shenzhen City (CN)

(72) Inventors: HE-LI WANG, Shenzhen City (CN); WEI LIU, Shenzhen City (CN); YONG-JUN YU, Shenzhen City (CN); XIAO-HUI ZHOU, Shenzhen City (CN)

(73) Assignees: HON HAI PRECISION INDUSTRY CO., LTD., Tu Cheng (TW); HONG FU JIN PRECISION INDUSTRY (ShenZhen) CO., LTD., Shenzhen City (CN)

(21) Appl. No.: 13/482,460

(22) Filed: May 29, 2012

(30) Foreign Application Priority Data
Nov. 8, 2011 (CN) 201110349607.7

(51) Int. Cl. H05K 5/00

(52) U.S. Cl. 361/679.01

(57) ABSTRACT

An electronic device includes a housing, a signal receiving unit receiving in the housing, and a detector window secured to the housing and corresponding to the signal receiving unit. The housing includes a top case having a front sidewall and a bottom case having a front side portion corresponding to the front sidewall. The front sidewall defines an opening for receiving a detecting window. Two limiting members receive the first end of the detector window and a holding member holds the second end of the detector window. When the top case covers the bottom case, the holding member engages with the limiting members to secure the detector window to the housing. A housing of an electronic device is also provided.

### BACKGROUND

1. Technical Field

The present disclosure relates to electronic devices; and particularly to an electronic device having a detector window.

2. Description of Related Art

An electronic device, such as a DVD player, includes a housing and a transparent detector window secured to the housing. The detector window includes a hook member. The housing defines an opening for allowing the detector window to be inserted therein, and includes a latching member arranged adjacent to the opening. The latching member corresponds to the hook member and hooks the hook member to secure the detector window to the housing. However, if the detector window is made of polymethyl methacrylate, which is very brittle, and the detector window may be broken when being secured to the housing by the hook member engaging with the latching member.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the four views.

FIG. 1 is a perspective view of an electronic device having a detector window in accordance with an embodiment.

FIG. 2 is a partially disassembled perspective view of the electronic device of FIG. 1.

FIG. 3 is similar to FIG. 2, but viewed from another aspect.

FIG. 4 is a cross-sectional view of the electronic device taken along line IV-IV in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

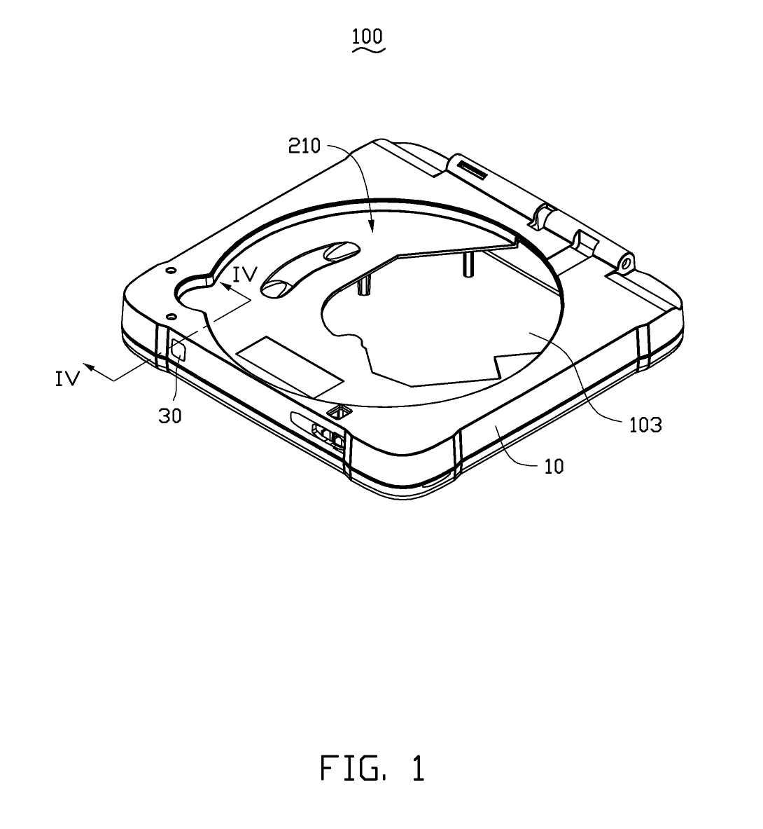

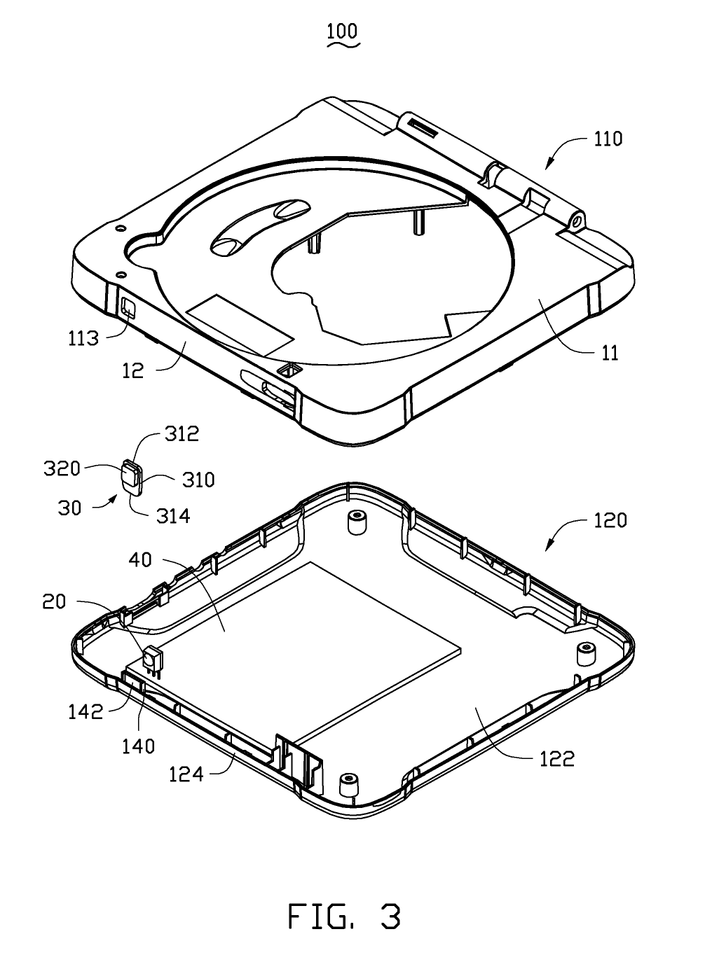

Referring to FIG. 1, a perspective view of an electronic device 100 in accordance with an embodiment is shown. The electronic device 100 includes a housing 10, a signal receiving unit 20 (see FIG. 3), and a detector window 30 secured to the housing 10 and corresponding to the signal receiving unit 20. The signal receiving unit 20 is used for receiving remote control signals via the detector window 30. In the embodiment, the electronic device 100 may be a portable disc player. The electronic device 100 further includes a disc cover (not shown) rotatably mounted to the housing 10. The disc cover allows discs (not shown) to be loaded and unloaded when the disc cover is open.

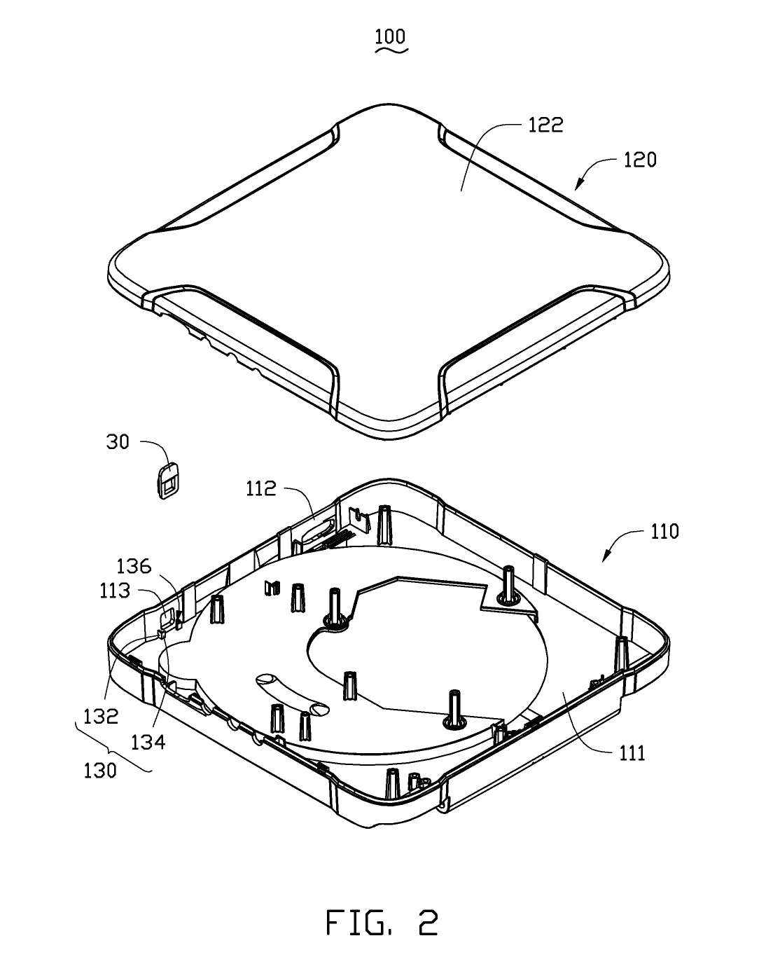

Referring also to FIGS. 2-3, the detector window 30 includes a base 310 and a window 320 arranged on the base 310. The base 310 is substantially rectangular, and includes a first end 312 and a second end 314 opposite to the first end 312. In the embodiment, the window 320 is arranged adjacent to the first end 312. When viewed from a front surface of the base 310, the window 312 protrudes out of the front surface of the base 310; when viewed from a rear surface of the base 310, the window 312 is recessed in the rear surface of the base 310. In the embodiment, the detector window 30 is made of polymethyl methacrylate and is substantially transparent.

The housing 10 is substantially rectangular, and includes a top case 110 and a bottom case 120. The top case 110 engages with the bottom case 120 to define a receiving space 103 for receiving the signal receiving unit 20 and other components (not shown) of the electronic device 100.

The top case 110 includes a top wall 111 and four sidewalls extending from the edges of the top wall 111. The top surface of the top case 110 opposite to the bottom wall 120 recesses to define a receiving groove 210 for receiving discs (not shown). When the electronic device is used, one of the sidewalls facing users (hereinafter, the front sidewall 112) defines an opening 113. The opening 113 is used for receiving the window 320 and allows the window 320 to be exposed out of the housing 10. The size of the opening 113 is less than that of the base 310, but is greater than that of the window 320. Two limiting members 130 are positioned on an inner surface of the front sidewall 112 and arranged at opposite sides of the opening 113. Each limiting member 130 includes an abutting portion 132 and a hook portion 134 bending from an end of the abutting portion 132 away from the front sidewall 112. The abutting portions 132 are parallel to each other and are perpendicular to the front sidewall 112 and to the top wall 111. The distance between the abutting portions 132 is slightly greater than the width of the first end 312 of the base 310. The hook portions 134 extend towards each other and cooperate with the abutting portions 132 to define a limiting space 136 for receiving the first end 312 of the base 310. The distance between each hook portion 134 and the front sidewall 112 is slightly greater than the thickness of the first end 312, such that the first end 312 is capable of being inserted into the limiting space 136.

The bottom case 120 includes a bottom wall 122 corresponding to the top wall 111 and four side portions extending from the edges of the bottom wall 122. The four side portions correspond to the four sidewalls, and one of the side portions corresponding to the front sidewall 112 is referred to herein as the front side portion 124. A holding member 140 is fixed to an inner surface of the front side portion 124. The holding member 140 is perpendicular to the bottom wall 122 and corresponds to the limiting members 130. The holding member 140 extends from the bottom wall 122 and extends out of the front side portion 124. An end of the holding member 140 abutting the front side portion 124 defines a receiving groove 142 for receiving the second end 314 of the base 310. The receiving groove 142 extends along the inner surface of the front side portion 124 and reaches the bottom wall 111. The width of the receiving groove 142 in horizontal cross-section is slightly greater than the width of the second end 314 of the base 310. When the top case 110 rests on the bottom case 120, the distance between the bottom of the receiving groove 142 and the top wall 111 is slightly greater than the distance between the first end 312 and the second end 314.

The electronic device 100 further includes a circuit board 40 positioned at an inner surface of the bottom wall 122. The signal receiving unit 20 is arranged at an end of the circuit board 40 adjacent to the front side portion 124 and corresponds to the limiting member 140.

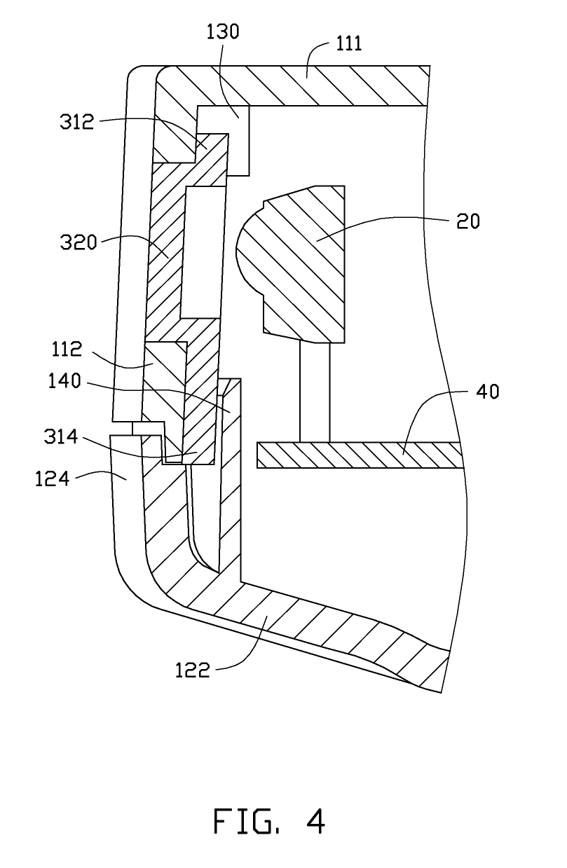

Referring to FIG. 4, in assembly, firstly, the first end 312 is inserted into the limiting space 136, and the window 320 is received in the opening 113. Secondly, the top case 110 is secured to the bottom case 120 with the second end 314 being received in the receiving groove 142. As the distance between the bottom of the receiving groove 142 and the top wall 111 is slightly greater than the distance between the first end 312 and the second end 314, the detector window 30 is stably secured to the housing 10 after the top case 110 is secured to the bottom case 120.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing comprising a top case and a bottom case, the top case having a front sidewall, the bottom case having a front side portion corresponding to the front sidewall;
a signal receiving unit received in the housing; and
a detector window secured to the housing and corresponding to the signal receiving unit, the signal receiving unit comprising a first end, a second end opposite to the first end, and a window arranged between the first end and the second end;
wherein the front sidewall defines an opening for receiving the window, two limiting members are positioned on an inner surface of the front sidewall and are arranged at opposite sides of the opening, the two limiting members cooperatively defines a limiting space for receiving the first end of the detector window; a holding member is positioned on an inner surface of the front side portion and corresponds to the limiting members, the holding member defines a receiving groove for holding the second end of the detector window; when the top case covers the bottom case, the holding member engages with the limiting members to steadily secure the detector window to the housing with the widow being in the opening and the first end and second being received in the limiting space and the receiving groove respectively.

2. The electronic device of claim 1, wherein the top case comprises a top wall, the front sidewall extends from a rim of the top wall.

3. The electronic device of claim 2, wherein each limiting member comprises an abutting portion perpendicular to the front sidewall and the top wall and a hook portion arranged at an end of the abutting portion away from front sidewall; the two abutting portions are parallel to each other, the two hook portions extend toward each other and cooperate with the abutting portions to define the limiting space.

4. The electronic device of claim 3, wherein the distance between the abutting portions is slightly greater than the width of the first end.

5. The electronic device of claim 3, wherein the distance between each hook portion and the front sidewall is slightly greater than the thickness of the first end.

6. The electronic device of claim 2, wherein the bottom case comprises a bottom wall, the front side portion extends from a rim of the bottom case, and the holding member extends from the bottom wall and extends out of the front side portion.

7. The electronic device of claim 6, wherein an end of the holding member abutting the front side portion defines a receiving groove for receiving the second end of the detector window.

8. The electronic device of claim 7, wherein the receiving groove extends along the inner surface of the front side portion and reaches the bottom wall.

9. The electronic device of claim 7, wherein the width of the receiving groove is slightly greater than the width of the second end of the detector window.

10. A housing of an electronic device for securing a detector window of the electronic device, the detector window comprising a first end, a second end opposite to the first end, and a window arranged between the first end and the second end, the housing comprising:
a top case having a front sidewall, the front sidewall defining an opening for receiving the window; and
a bottom case engaging with the top case and comprising a front side portion corresponding to the front sidewall;
wherein two limiting members are positioned on an inner surface of the front sidewall and are arranged at opposite sides of the opening, the two limiting members cooperatively defines a limiting space for receiving the first end of the detector window; a holding member is positioned on an inner surface of the front side portion and corresponds to the limiting members, the holding member defines a receiving groove for holding the second end of the detector window; when the top case covers the bottom case, the holding member engages with the limiting members to steadily secure the detector window to the housing with the widow being in the opening and the first end and second being received in the limiting space and the receiving groove respectively.

11. The housing of claim 10, wherein the top case comprise a top wall, the front sidewall extends from a rim of the top wall.

12. The housing of claim 11, wherein each limiting member comprises an abutting portion perpendicular to the front sidewall and to the top wall and a hook portion arranged at an end of the abutting portion away from front sidewall; the two abutting portions are parallel to each other, the two hook portions extend toward each other and cooperate with the abutting portions to define the limiting space.

13. The housing of claim 12, wherein the distance between the abutting portions is slightly greater than the width of the first end.

14. The housing of claim 12, wherein the distance between each hook portion and the front sidewall is slightly greater than the thickness of the first end.

15. The housing of claim 11, wherein the bottom case comprises a bottom wall, the front side portion extends from a rim of the bottom case, and the holding member extends from the bottom wall and extends out of the front side portion.

16. The housing of claim 15, wherein an end of the holding member abutting against the front side portion defines a receiving groove for receiving the second end of the detector window.

17. The housing of claim 16, wherein the receiving groove extends along the inner surface of the front side portion and reaches the bottom wall.

18. The housing of claim 16, wherein the width of the receiving groove is slightly greater than the width of the second end of the detector window.
